(19) United States
(12) Patent Application Publication
(10) Pub. No.: US 2005/0266668 A1
(43) Pub. Date: Dec. 1, 2005

(54) Semiconductor device and method of manufacturing the same

(76) Inventors: Kanako Sawada, Yokohama-shi (JP); Toshitsune lijima, Tokyo (JP); Soichi Homma, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/137,537

(22) Filed: May 26, 2005

(30) Foreign Application Priority Data
May 28, 2004 (JP) P2004-160322

(51) Int. Cl. H01L 21/44

(52) U.S. Cl. 438/612

(57) ABSTRACT

A semiconductor device comprises a semiconductor element having first electrode pads and solder bumps, and a substrate having second electrode pads connected to the first electrode pads via the solder bumps. The semiconductor element has an insulating film with a low dielectric constant. The group of the solder bumps is provided with a solder bump in which a stress intensity factor K in a notch shape formed by the first electrode pad and the outline of the solder bump, when looking at a cross section through the center of the first electrode pad and the solder bump, is such that on the chip edge side it is less than or equal to its value on the chip center side. Thereby, cracking or delamination of the semiconductor element due to the insulating film with a low dielectric constant can be restrained.

### CROSS-REFERENCE TO THE INVENTION

This application is based upon and claims the benefit of priority from the prior Japanese Patent Application No. 2004-160322, filed on May 28, 2004; the entire contents of which are incorporated herein by reference.

### BACKGROUND OF THE INVENTION

1. Field of the Invention

The present invention relates to a semiconductor device to which a flip chip connection is applied, and a method of manufacturing the same.

2. Description of the Related Art

In recent years, in order to cope with increasing terminals, finer pitches, higher signal speed, higher heat generation and so on of semiconductor elements (semiconductor chips), a flip chip connection is used as a mounting system having short wiring and connection lengths. A semiconductor element used to the flip chip connection has electrode pads formed in an area array, for instance, and solder bumps formed on these electrode pads. A substrate on which a semiconductor element is mounted has electrode pads formed at positions corresponding to the electrode pads on the semiconductor element. The surface of the electrode pad on the substrate side is made of gold (Au), solder, or the like so that it gets wet when the solder bump is melted.

A flip chip connection is a method of connection between electrode pads of a semiconductor element and a substrate by melting the solder bump after positioning the electrode pads of the semiconductor element and the substrate so as to face to each other. In order to deoxidize the solder, flux is usually applied on the substrate or the semiconductor element. An underfill resin is injected between the semiconductor element and the substrate after connection to fix the semiconductor element by curing the underfill resin. It is also practiced to apply a no-flow-underfill resin containing flux directly on the substrate as a simpler bonding process, so as to skip processes of rinsing out flux or injecting an underfill resin.

In order to cope with further pursuing of finer pitch or higher speed of a semiconductor element, use of copper (Cu) wiring to realize lowering of resistance of wiring, and application of an insulating film (low-k film) having a low dielectric constant (low-k) to reduce capacitance between wirings have been promoted. The lowest physical value of the dielectric constant is 1 in a vacuum case. That is, the more porous in the material to be used, the lower the relative dielectric constant. However, since the low-k material having holes inside is weak in mechanical strength, a semiconductor element having a low-k film has a disadvantage of easily generating cracking, delaminating, or the like due to the low-k film when the flip chip connection is used.

As a cause of generating delaminating, cracking, or the like, a difference in thermal expansion coefficient between a semiconductor element and a substrate in the heat-melting process of a solder bump can be cited. Compared with the thermal expansion coefficient of a semiconductor element, which is about 3 ppm, the thermal expansion coefficient of a substrate is higher, and especially in a resinous substrate, may be 10 ppm or more. The electrode pads of a semiconductor element and those of a substrate are usually designed such that their positions are matched at room temperature. In other words, the pitch of the electrode pads of a semiconductor element and the pitch of the electrode pads of a substrate are equal in a state at room temperature.

As shown in FIG. 10A, after aligning electrode pads 2 of a semiconductor element 1 and electrode pads 4 of a substrate 3 in a state at room temperature (Tᵣₜ), they are put in a reflow oven to heat and melt solder bumps 5. Since the thermal expansion coefficient of the substrate 3 is larger than that of the semiconductor element 1, a pad pitch of the substrate 3 expands more than that of the semiconductor element 1 in a state of reflow temperature (Tᵣ), as shown in FIG. 10B. As a result, the electrode pads 2 of the semiconductor element 1 and the electrode pads 4 of the substrate 3 become misaligned. In this state, the solder bumps 5 are distorted towards the chip center, but no stress occurs in the solder bumps 5 because they are melted.

When the molten solder bumps 5 are cooled to the solidification temperature (Tₘ), the amount of deformation becomes small. However, since the pad pitch of the substrate 3 is wider than that of the semiconductor 1, the solder bumps 5 distort toward the chip center side. Though the deformation of the solder bumps 5 decreases while being cooled to room temperature (Tᵣₜ), the internal stress of the solder bumps 5 becomes conversely large. Since the semiconductor element 1 and the substrate 3 are connected with a large number of solder bumps 5, both pad pitches can not be in complete correspondence with each other when cooled to room temperature. Therefore, as shown in FIG. 10C, the deformation of the solder bumps 5 toward the chip center still remains.

Since the pad diameter is usually as wide as about 100 μm, and the self-alignment effect of the solder bumps 5 also works, the deformation of the solder bumps 5 in a solidification state and a room temperature state would not be so large as to hinder the connection. However, since the low-k film is low in mechanical strength, crack and delamination is easily generated by stress based on the deformation of the solder bumps 5. Thus, the deformation of the solder bumps 5 towards the chip center as shown in FIG. 10C and increase in the internal stress of the solder bumps 5 are the causes of cracking, delamination, and the like of a low-k film which is low in mechanical strength.

It should be noted that it is described in Japanese Patent Laid-open Application No. Hei 5-29389 that a solder bump is formed on a protruded portion in a cantilever structure to restrain share stress generated in the solder bump based on a difference in an amount of thermal deformation between a semiconductor element and a substrate. With such a connection structure, it is impossible to adequately cope with increasing terminals and becoming finer pitches of semiconductor elements. In Japanese Patent Laid-open Application No. Hei 6-13431, a structure is described in which pad positions are established so as to match the electrode pads of the semiconductor element and the substrate with each other at the temperature of device operation in a dual-layered structure bump where bumps are provided on both the semiconductor element and the substrate. However, no consideration is given to increase in deformation of the solder bump or increase in internal stress owing to a flip chip connecting process, and a shape of a connecting portion (a connecting portion of a solder bump) to restrain cracking, delamination or the like of a low-k film is not shown.

In Japanese Patent Laid-open Application No. 2002-26072, a structure is described in which a formative pitch of electrode pads of a substrate differentiates from a formative pitch of bump electrodes in a structure connecting the bump electrodes (Au bumps) of a semiconductor element and the electrode pads of the substrate via anisotropic conductive resin. In this structure, a contact area between the Au bump of the semiconductor element and the electrode pad of the substrate is secured by preventing shifting of position at a temperature of melting and hardening the anisotropic conductive resin. However, no consideration is given to deformation of the Au bumps and increase of the internal stress originated in the flip chip connecting process. That is, a connecting portion (a connecting portion by the solder bump) to restrain cracking, delamination, or the like of a low-k film originated in the flip chip connecting process is not shown.

As described above, though a semiconductor element using a low dielectric constant insulation film (low-k film) is effective in handling the finer pitch of wiring, higher speed, and the like, it has a disadvantage in that cracking, delamination, and the like are apt to occur in the low-k film which is low in mechanical strength in the case of a conventional flip chip connection. This is a main cause to lower a manufacturing yield of semiconductor device in which a semiconductor element is connected in a flip chip connection on a substrate. Under such circumstances, it is desired to provide a connecting structure capable of restraining occurrences of cracking, delamination, and the like due to the low-k film which is low in mechanical strength.

### SUMMARY OF THE INVENTION

Accordingly, an object of the present invention is to provide a semiconductor device which makes it possible to improve manufacturing yield and reliability in a connecting process between a semiconductor element and a substrate, by restraining cracking, delamination, or the like of an insulating film with a low dielectric constant originated in the flip chip connecting process, and a method of manufacturing the same.

A semiconductor device relating to an embodiment of the present invention comprises: a semiconductor element including a element body having an insulating film with a low dielectric constant, a group of electrode pads having first electrode pads formed on the element body, and a group of solder bumps having solder bumps formed on the first electrode pads respectively; and a substrate provided with a group of electrode pads having second electrode pads connected to the first electrode pads via the solder bumps, in which the group of solder bumps is provided with a solder bump having a stress relaxation shape in which a stress intensity factor in a notch shape formed by the first electrode pad and the outline of the solder bump, when looking at a cross section through the center of the first electrode pad and the solder bump, is such that on the edge side of the semiconductor element it is less than or equal to its value on the center side of the semiconductor element.

A method of manufacturing a semiconductor device relating to an embodiment of the present invention comprises: aligning a semiconductor element provided with a element body having an insulating film with a low dielectric constant and a first electrode pad arranged on the element body and a substrate having a second electrode pad so that the first electrode pad corresponds with the second electrode pad via a solder bump formed on the first electrode pad; melting the solder bump by heating the aligned semiconductor element and substrate under a heating condition that the temperature of the substrate is lower than the temperature of the semiconductor element; and cooling the melted solder bump and connecting the first electrode pad of the semiconductor element and the second electrode pad of the substrate via the solder bump having a shape in which a stress intensity factor in a notch shape formed by the first electrode pad and the outline of the solder bump, when looking at a cross section through the first electrode pad and the solder bump, is such that on the edge side of the semiconductor element it is less than or equal to its value on the center side thereof.

### BRIEF DESCRIPTION OF THE DRAWINGS

The present invention will be described with reference to the drawings, but these drawings are presented only for the illustrative purpose and in no respect are intended to limit the present invention.

FIG. 1 is a conceptual diagram explaining stress concentration when a notch is present in a homogeneous material.

FIG. 2 is a graph showing a relation between stress and distance from the center of the notch, when a notch is present in a homogeneous material.

FIG. 3 is a conceptual diagram explaining stress concentration when a notch is present on a bonded interface between two materials.

FIG. 4 is a sectional view showing a general configuration of semiconductor device according to an embodiment of the present invention.

FIG. 5 is a sectional view showing a configuration of an essential portion of a semiconductor element applied to the semiconductor device shown in FIG. 4.

FIG. 6 is a sectional view showing a configuration of an essential portion of the semiconductor device shown in FIG. 4.

FIG. 7 is a view showing an example of pad alignment of a substrate applied to a semiconductor device according to an embodiment of the present invention.

FIGS. 8A, 8B, and 8C are sectional views showing a manufacturing process of an essential portion of a semiconductor device according to an embodiment of the present invention.

FIGS. 9A, 9B, and 9C are sectional views showing a manufacturing process of an essential portion of a semiconductor device according to another embodiment of the present invention.

FIGS. 10A, 10B, and 10C are sectional views showing a manufacturing process of an essential portion of a conventional semiconductor device.

### DESCRIPTION OF THE EMBODIMENTS

Embodiments of the present invention will be explained with reference to the drawings as follows. It should be noted that though embodiments of the present invention will be described hereinafter based on the drawings, but these drawings are presented only for the illustrative purpose and the present invention is not limited to the drawings.

In a semiconductor device (semiconductor module) relating to an embodiment of the present invention, a semiconductor element (semiconductor chip) mounted on a substrate is provided with a element body having an insulating film with a low dielectric constant, a group of electrode pads having first electrode pads arranged on the element body, and a group of solder bumps having solder bumps formed on the first electrode pads respectively. The group of solder bumps has a solder bump in which the stress intensity factor in the notch shape formed by the first electrode pad and the outline of the solder bump, in a cross section through the center of the first electrode pad and the solder bump, is such that on the edge side (chip edge side) of the semiconductor element it is less than or equal to its value on the center side (chip center side).

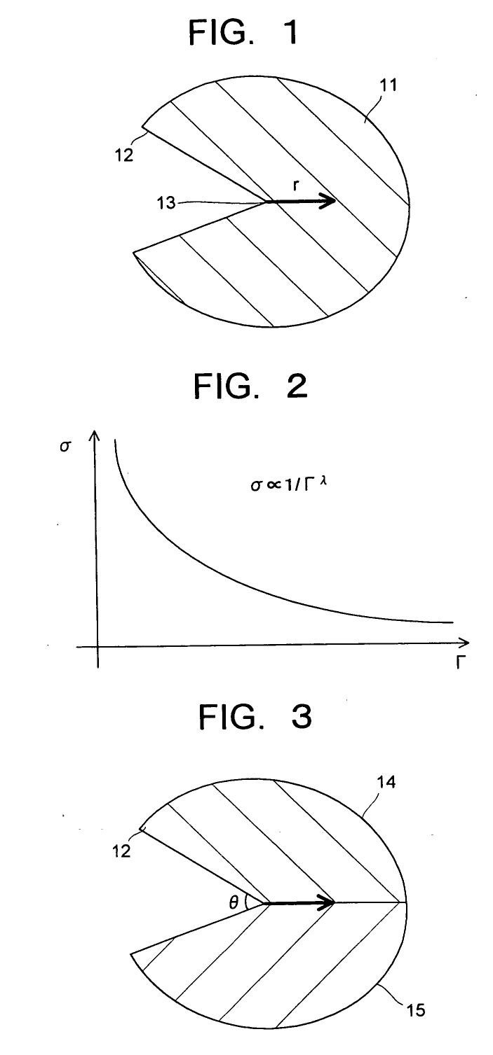

As shown in FIG. 1, when a notch 12 is present in a homogeneous material 11, it is known that stress in the vicinity of a notch center 13 forms a stress singular field in which the notch center 13 serves as an origin. That is, as shown in FIG. 2, the stress σ in the vicinity of the notch center 13 is expressed by an equation (1) below. The stress σ concentrates in the vicinity of the origin of the notch center 13.
σ ∝ 1/r^{λ} (1)

In fracture mechanics, the stress σ in the vicinity of the notch center 13 is expressed by the following equation (2), using a coefficient K which is determined by the structure of the notch 12.
σ=K/(2πr)^{1/2} (2)
where, r is a distance from the origin.

The coefficient K in the equation (2) is called a stress intensity factor, and expresses the easiness with which cracking propagates. The larger the stress intensity factor K, the easier cracking propagates. Further, the sharper and longer the notch 12, the greater the ease with which cracking propagates even under forces of the same magnitude.

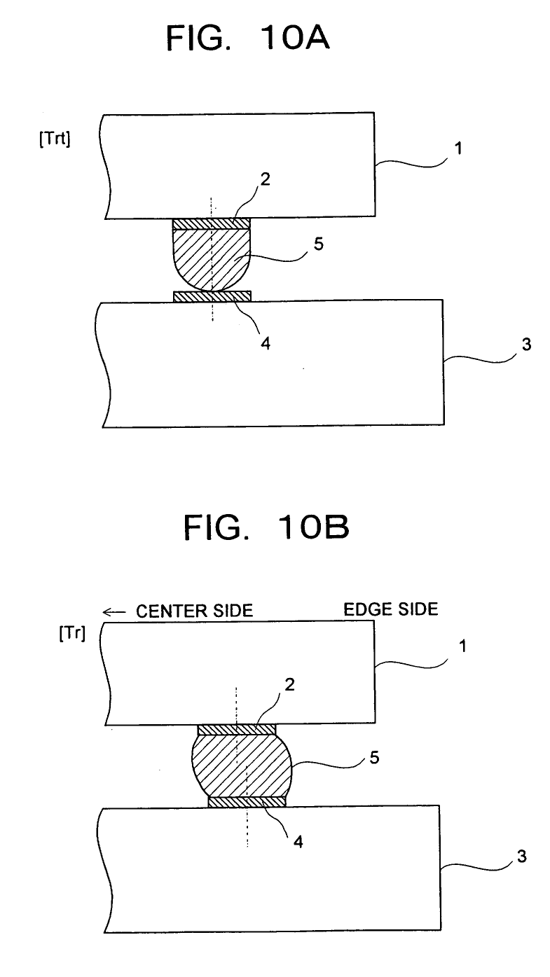

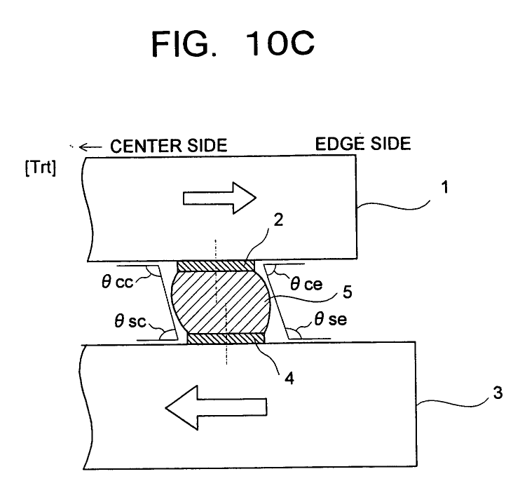

As shown in FIG. 3, even when cracking propagates from an end of an interface where a first material 14 and a second material 15 are bonded to each other, as for the stress and the stress intensity factor, they are basically the same, though its equation expressing stress becomes complicated. Its stress intensity factor K is defined in the same manner as in FIG. 1, and when the notch angle θ is smaller, the degree of stress concentration is greater. Accordingly, if a stress intensity factor K at a portion where cracking easily propagates can be made small, crack resistance can be improved. As shown in FIG. 10C, in a semiconductor device to which a conventional flip chip connection is applied, the solder bumps 5 after connection have a shape distorting towards a chip center side. Easiness in crack propagation in a notch shape formed between the electrode pads 2 and the outline of the solder bumps 5 is explained in FIG. 3.

In the solder bump 5 distorting towards the chip center side, the angle θ_{ce} on the chip edge side of the notch shape formed between the electrode pads 2 and the outline of the solder bumps 5 is smaller than the angle θ_{cc} on the chip center side thereof, as shown in FIG. 10C. Therefore, cracking easily starts from the corner portion on the chip edge side (the portion having an angle of θ_{ce}). In the notch shape formed between the electrode pads 4 of the substrate 3 and the outline of the solder bumps 5, the angle θ_{sc} on the substrate center side is smaller than the angle θₛₑ on the substrate edge side. However, in the cooling process of the connecting process, forces shown by the arrow in FIG. 10C operates such that compression stress works on the corner portion on the substrate center side (the portion having an angle of θ_{sc}). Accordingly, cracking does not easily start from the corner portion on the substrate center side.

Thus, in the cooling process of the solder bump from the melting temperature (Tr) to the solidification temperature (Tₘ), and further to room temperature (Tᵣₜ), cracking occurred due to a difference in thermal expansion coefficient between a semiconductor element and a substrate can be restrained by making a stress intensity factor K of the corner portion on the chip edge side (the portion having an angle of θ_{ce}) small. More concretely, in the process from the melting temperature (Tᵣ) of the solder bumps to the room temperature (Tᵣₜ) thereof, the stress intensity factor K at the corner portion on the chip edge side of the solder bumps (the portion having an angle of θ_{ce}) is made small. By applying such a connection shape (shape of the solder bumps), it becomes possible to improve crack resistance of a semiconductor element.

In a semiconductor device relating to an embodiment of the present invention, a group of solder bumps is aligned in a matrix array. In the group of solder bumps having such an alignment, cracking is apt to occur in solder bumps arranged on the edge of a bump forming region, especially in the corners. Accordingly, it is effective to control the stress intensity factor K on the chip edge side of the solder bumps positioned at least at the corners of the bump forming region to be small. The solder bumps to make the stress intensity factor K small are only at the corner portions of the bump forming region. Then, crack resistance of a semiconductor element can be improved.

A semiconductor device relating to an embodiment of the present invention has solder bumps formed on the first electrode pads of which center is shifted to more chip edge side from the center of the second electrode pads on the substrate side at room temperature, as a solder bump having a small stress intensity factor on the chip edge side. Anticipating that the pad pitch on the substrate side will become wider than the pad pitch on the semiconductor element side at a melting temperature of the solder bumps, the center of the first electrode pad is shifted in advance towards the chip edge side away from the center of the second electrode pad at room temperature. Thereby, the stress intensity factor K at the corner portion on the chip edge side of the solder bump after the connecting process (a reflowing process of the solder bump) can be made small.

Further, in a connecting process to heat and melt solder bumps, by setting heating conditions such that the temperature of the substrate is lower than that of the semiconductor element, the amount of deformation of the solder bumps can be reduced. Thus, by reducing the deformation of the solder bumps in the connecting process, the stress intensity factor K on the chip edge side of the solder bumps can also be reduced. The stress intensity factor K described here indicates a stress intensity factor in a notch shape formed by the first electrode pad and the outline of the solder bump (a portion having an angle of θ).

It is preferable to establish an amount to shift the center of the first electrode pads from the center of the second electrode pads based on a thermal expansion coefficient E_{c} of the semiconductor element, a thermal expansion coefficient Eₛ of the substrate, a melting temperature Tᵣ of the solder bumps, and a distance r of the solder bumps to be considered from the center of the semiconductor element (at room temperature). Concretely, it is preferable to establish an amount of shift (Δr) between the center of the first electrode pads and the center of the second electrode pads in a range expressed by the following equation (3).
10 μm≦Δr≦(Tᵣ−Tᵣₜ)·r·(Eₛ−E_{c}) (3)

As described previously, when heated to the melting temperature Tᵣ of the solder bumps, since the thermal expansion coefficient Eₛ of the substrate is greater than the thermal expansion coefficient E_{c} of the semiconductor element, the pad pitch of the substrate is wider than the pad pitch of the semiconductor element. That is, the amount of thermal expansion Δr_{c} of the semiconductor element at the melting temperature Tᵣ of the solder bumps is expressed by the following equation (4). On the other hand, the amount of thermal expansion Δrₛ of the substrate is expressed by the following equation (5). The maximum difference between these values (Δrₛ−Δr_{c}) can be expressed by the following equation (6).
Δr_{c}=(Tᵣ−Tᵣₜ)·r·E_{c} (4)
Δrₛ=(Tᵣ−Tᵣₜ)·r·Eₛ (5)
Δrₛ−Δr_{c}=(Tᵣ−Tᵣₜ)·r·(Eₛ−E_{c}) (6)

Accordingly, by shifting the center of the first electrode pads from the center of the second electrode pads so that the amount of shift Δr at room temperature is within the range of [(Tᵣ−Tᵣₜ)·r·(Eₛ−E_{c})], the stress intensity factor K on the chip edge side of the solder bumps can be made small. When the amount of shift Δr at room temperature is made larger than the value of [(Tᵣ−Tᵣₜ)·r·(Eₛ−E_{c})], the amount of deformation of the solder bumps after melting and cooling becomes too large, which may cause connection failure and the like. On the contrary, if the amount of shift Δr at room temperature is too small, reduction effect of the stress intensity factor K on the chip edge side cannot be obtained sufficiently. Therefore, the amount of shift Δr is preferably 10 μm or more.

In a semiconductor device relating to an embodiment of the present invention, a semiconductor element includes an insulating film with a low dielectric constant (low-k film) having a relative dielectric constant of, for instance, 3.5 or less. As described above, since the insulating film with a low dielectric constant (low-k film) applied to an interlayer insulating film or the like is low in mechanical strength, cracking, delamination, or the like are generated by a stress which usually does not cause a problem with an ordinary semiconductor element. Accordingly, when such a semiconductor element having a low-k film is connected in a flip chip connection to a circuit board, a suppression effect against cracking or the like due to reduction of a stress intensity factor K on the chip edge side works effectively. In other words, cracking, delamination, and the like due to the low-k film of the semiconductor element can be effectively controlled. It should be noted that reduction of the stress intensity factor K on a chip edge side works effectively even to a semiconductor element having a low strength interlayer film or the like except a low-k film.

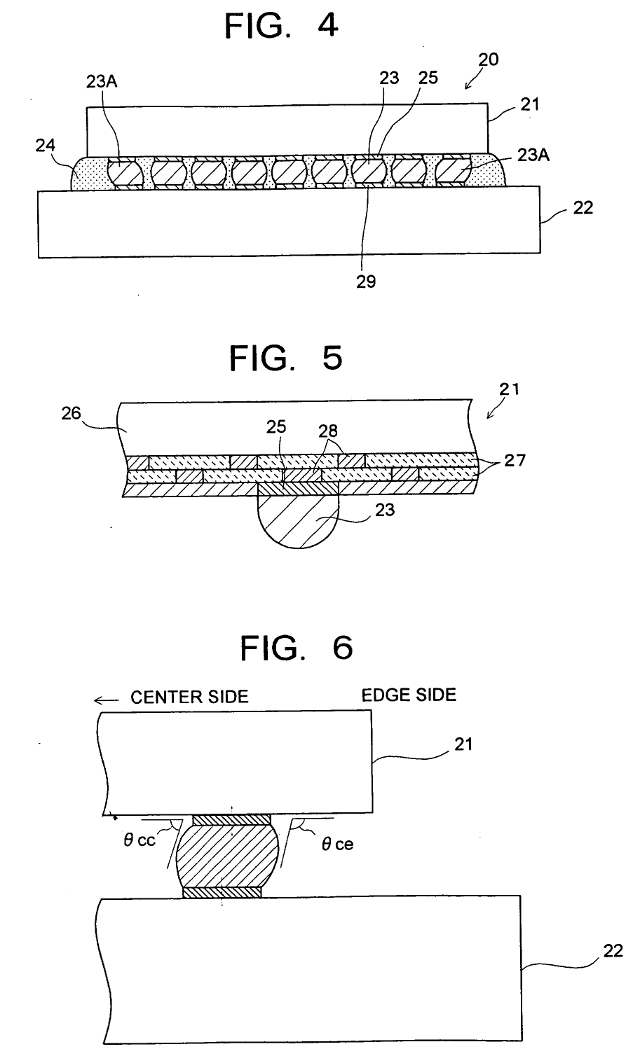

Based on the above-described points, embodiments of the semiconductor device of the present invention will be explained with reference to the drawings. FIG. 4 is a view showing a general configuration of a semiconductor device according to an embodiment of the present invention. The semiconductor device (semiconductor module) 20 shown in the figure has a structure electrically connecting a semiconductor element 21 having an insulating film with a low dielectric constant (low-k film) to a substrate 22 with a plurality of solder bumps 23. In other words, the semiconductor device 20 has a structure of a flip chip connection. In a gap between the semiconductor element 21 and the substrate 22, an underfill resin 24 is injected and cured. As the underfill resin 24, thermosetting resin such as epoxy resin is used, for instance.

On one surface of the semiconductor element 21, a group of the first electrode pads having a plurality of electrode pads 25 are formed. The first electrode pads 25 are composed of, for instance, multi-layered metal films, considering barrier properties, wettability, and the like. As a concrete example of the first electrode pads 25, aluminum (Al) pads may be formed on copper (Cu) pads, and on the surface of the aluminum pads, a titanium (Ti) film, a nickel (Ni) film and a palladium (Pd) film are formed in layers in this order. However, the first electrode pads 25 are not limited to this, and various single-layered or multi-layered metal layers can be used.

The solder bumps 23 are formed on the electrode pads 25 on the semiconductor element 21 side respectively, which form a group of solder bumps. In order to cope with a growing number of pins, the solder bumps 23 are arranged in a matrix array within a predetermined region. Such solder bumps 23 are formed by, for instance, electroplating. The solder bumps 23 by electroplating are typically formed through respective processes such as formation of a metal layer to be an electrode for the plating, application of resist, opening of pad portions, electrolytic plating, removal of the resist, removal of unnecessary metal layers, and so on. Sn—Pb eutectic solder or the like is used for the solder bumps 23, but it is possible to use solder made of various metals in addition to this material.

As shown in FIG. 5, the semiconductor element 21 includes a semiconductor substrate (for instance, Si substrate) 26 as a element body. On a element forming region side of the semiconductor substrate 26, formed is a circuit portion composed of an interlayer insulating film made of an insulating film with a low dielectric constant (low-k film) 27 and Cu wiring 28. The first electrode pads 25 are electrically connected to the Cu wiring 28. It is preferable to use material having a relative dielectric constant of 3.5 or less for the low-k film 27 as an interlayer insulating film.

As examples of the low-k film 27 with a relative dielectric constant of 3.5 or less, a fluorine doped silicon oxide film (SiOF film), a carbon doped silicon oxide film (SiOC film), an organic silica film, an HSQ (hydrogen silsesquioxane) film, an MSQ film (methyl silsesqioxane film), a PAE (polyarylether) film, a PTFE (polytetrafluoroethylene) film, a BCB (benzocyclobutene) film, a porous film of these materials, and a porous silica film are cited.

The thermal expansion coefficient of the substrate 22 on which the semiconductor element 21 is mounted is generally larger than that of the semiconductor element 21. As such a substrate 22, an insulative substrate such as a resin substrate, a ceramic substrate, a glass substrate, or the like is used. A circuit is formed on the surface or inside the insulative substrate to be used for a circuit board. A commonly available multi-layered printed circuit board is a typical example of a circuit board using a resin substrate. On the surface of the substrate 22, second electrode pads 29 are formed respectively on the positions corresponding to solder bumps 23, composing a group of second electrode pads. The surface of the second electrode pads is covered with a film of gold (Au), a solder layer, or the like from a point of view of wettability with the solder bump 23, corrosion resistance, and the like. Portions other than the second electrode pads 29 are protected with a resist or the like.

In the above-described semiconductor device 20, the group of solder bumps electrically connecting the semiconductor element 21 and the substrate 22 has a solder bump 23A in which the stress intensity factor K in the notch shape (portion having an angle θ) formed by the first electrode pad 25 and the outline of the solder bump 23, in a cross section through the center of the first electrode pad 25 and the solder bump 23 as shown in FIG. 6, is such that on the edge side of the semiconductor element 21 it is less than or equal to its value on the center side thereof. In other words, in the notch shape formed by the first electrode pad 25 and the outline of the solder bump 23, when the stress intensity factor in the notch shape on the chip center side is defined as K_{cc}, and that in the notch shape on the chip edge side is defined as K_{ce}, the solder bump 23A satisfies K_{cc}≧K_{ce}.

The shape of the solder bump 23A will be described in detail. In a notch shape formed by the first electrode pad 25 and the outline of the solder bump 23A shown in FIG. 6, the angle θ_{ce} on the chip edge side is larger than the angle θ_{cc} on the chip center side. Since stress concentration is more relaxed when a notch angle θ is larger, cracking is unlikely to easily propagate. Applying this tendency to the stress intensity factor K, the corner portion on the chip edge side (portion with an angle of θ_{ce}) has stress intensity factor equal to or lower than the chip center side (portion with an angle of θ_{cc}). As described above, since cracking easily starts from the corner portion (portion with an angle of θ_{ce}) of the chip edge side as described above, the solder bump 23A having a small stress intensity factor K_{ce} in this portion, in other words, the solder bump 23A having a shape which relaxes stress (stress relaxation shape) greatly contributes to improvement in crack resistance of the semiconductor element 21.

Thus, in the cooling process of the solder bumps from the melting temperature (Tᵣ) to the solidification temperature (Tₘ), and further to room temperature (Tᵣₜ), by controlling the shape of solder bump 23A so that the stress intensity factor K_{ce} in the corner portion on the chip edge side (portion with an angle of θ_{ce}) is small, it becomes possible to relax stress concentration to a corner on the chip edge side. Accordingly, in the semiconductor element 21 having a low-k film 27 low in mechanical strength, it is possible to effectively restrain the occurrence of cracking or fracturing due to the low-k film 27. Though the same can be said when the stress intensity factor K_{ce} in the corner on the chip edge side is made equal to the stress intensity factor K_{cc} in the corner on the chip center side, in order to reproductively enhance crack resistance, it is desirable to control the stress intensity factor K_{ce} in the corner on the chip edge side to be smaller than the stress intensity factor K_{cc} in the corner on the chip center side (K_{cc}>K_{ce})

It is essentially preferable from a viewpoint of preventing occurrence of stress not to deform the shape of the solder bumps 23. However, since the semiconductor element 21 differs from the substrate 22 in the thermal expansion coefficient as described above, deformation of the solder bumps 23 cannot be avoided in the process of melting the solder bump 23. In such a case, the stress intensity factor K_{ce} in the corner on the chip edge side is made less than or equal to the stress intensity factor K_{cc} in the corner on the chip center side in a notch shape at the cross section of the solder bump 23A, thereby enhancing the crack resistance of the corner portion on the chip edge side where cracking is apt to occur.

As described above, by enhancing crack resistance of the corner portion on the chip edge side among corner portions formed by the semiconductor element 21 and the solder bumps 23A, it becomes possible to effectively restrain cracking occurred in the low-k film 27 low in mechanical strength, based on the difference in thermal expansion coefficient between the semiconductor element 21 and the substrate 22. Thereby, it becomes possible to suppress occurrence of failure originated from the flip chip connecting process of the semiconductor element 21 having the low-k film 27. Though the stress intensity factor K becomes large in a corner portion (portion with an angle of θ_{cc}) on the chip center side, since compression stress works on this portion during the cooling process, cracking is not likely to start from the corner portion on the chip center side.

Though the solder bump 23A with a small stress intensity factor K_{ce} of the corner portion on the chip edge side can be applied to all of the solder bumps 23, it is preferable to preferentially apply the solder bump 23A to the solder bumps 23 of corner portions. Since the amount of shift based on the difference in a thermal expansion coefficient between the semiconductor element 21 and the substrate 22 is proportional to the distance r from the center of the semiconductor element 21 to the solder bump 23, as is clear from the equation (4), the maximum stress is added to the solder bump 23 in the corner portion where the distance r is largest. Accordingly, it is effective to preferentially apply the solder bump 23A from corner portions.

The solder bump 23A having a stress relaxation shape contributes to improvement of crack resistance of the semiconductor element 21 with the low-k film even when application is restricted to the corner portions. In the semiconductor device 20 shown in FIG. 4, the solder bumps 23A where the stress intensity factor K_{ce} of the corner portion on the chip edge side is made small are arranged in four corners of the group of solder bumps aligned in an area array. It is possible to restrain the occurrence of cracking or delaminating on the low-k film 27 of the semiconductor element 21 by this formation alone. Needless to say, it is possible to effectively restrain cracking, delamination or the like of the low-k film 27 of other solder bumps 23 by using a similar formation.

Cracking or delaminating due to the low-k film 27 low in mechanical strength is caused by deformation or increase of internal stress of the solder bumps 23 in the flip chip connecting process as described above. Therefore, it is possible to restrain cracking or delamination of the low-k film 27 originated from the connecting process by applying a stress relaxation shape to the solder bumps 23A at four corners where the maximum stress is added in the flip chip connecting process. Since reliability of the semiconductor element 21 after the connecting process is secured by the underfill resin 24, it is possible to realize reduction in an occurrence rate of failure of the semiconductor element 21 and improvement in reliability of the semiconductor element 21 by restraining cracking or delamination of the low-k film 27 in the connecting process.

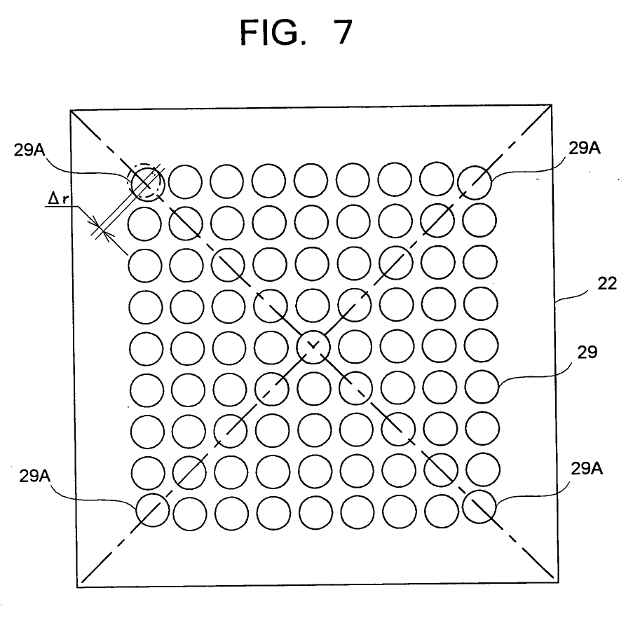

The solder bump 23A as shown in FIG. 6 can be obtained by shifting the center of the first electrode pad 25 at room temperature to the chip edge side from the center of the second electrode pad 29 in advance. As a concrete method, as shown in FIG. 7 for example, a method of shifting the center of the second electrode pads 29A in four corners to the substrate center side from the center of the first electrode pads 25 corresponding thereto by a distance of Δr is cited. Since several kinds of substrates 22 are used with respect to the semiconductor element 21 according to the usage or the like, it is effective to shift the center of the second electrode pads 29A of the substrate 22.

It is preferable to set the amount of shift Δr between both centers of the first electrode pad 25 and the second electrode pad 29 according to the size of the semiconductor element 21, the kind of the substrate 22 or the like. More concretely, it is preferable to set the amount of shift Δr so that it is within the range of the equation (1). The maximum amount of shift Δr is (Tᵣ−Tᵣₜ)·r·(Eₛ−E_{c}), and it is preferable to set the amount of shift within this range, considering a connective margin or the like. However, if the amount of shift Δr is too small, since it is impossible to effectively reduce the stress intensity factor K_{ce} of the corner on the chip edge side, it is preferable to set the amount of shift Δr at room temperature to 10 μm or more.

For instance, when the shape of the semiconductor element 21 is 18 mm×18 mm, the thermal expansion coefficient E_{c} of the semiconductor element 21 is 3 ppm, and the thermal expansion coefficient Eₛ of the substrate 22 is 13 ppm, it is preferable to form the first electrode pads 25A corresponding to the four corners of the group of solder bumps by shifting them from the second electrode pads 29 towards the chip edge by 10 to 20 μm. A similar situation is preferable when the second electrode pads 29A corresponding to the four corners of the group of solder bumps are formed shifted towards the substrate center.

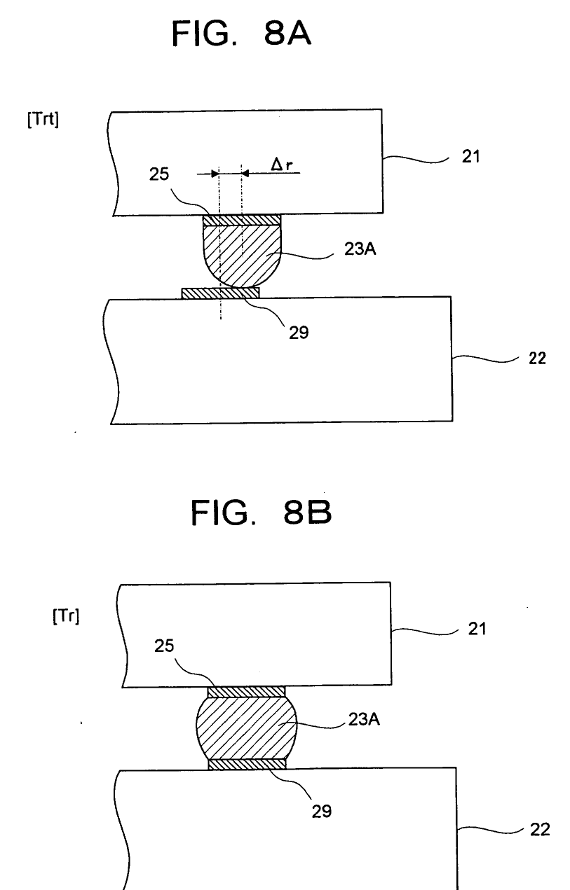

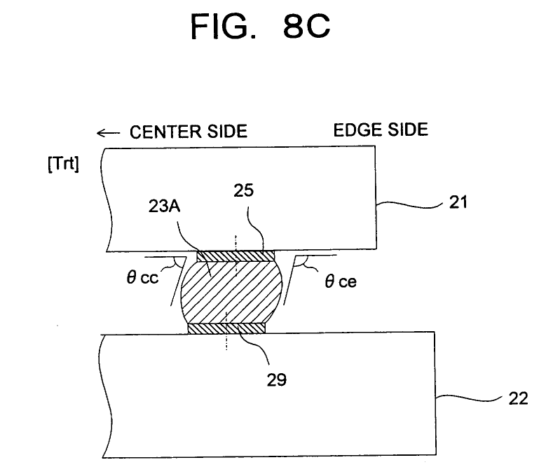

The behavior of the solder bump 23A which establishes the amount of shift Δr between the first electrode pad 25 and the second electrode pad 29 in the process of connection as well as the manufacturing process of the semiconductor device 20 will be explained with reference to FIGS. 8A to 8C. First, the substrate 22 is coated with a flux agent (not shown). The flux agent can be supplied to the semiconductor element 21 side. Then, as shown in FIG. 8A, positioning of the semiconductor element 21 and the substrate 22 is performed using a bonder (not shown). The solder bumps 23A positioned in four corners of the group of solder bumps are aligned shifted with respect to the second electrode pads 29 by Δr. The other solder bumps 23 are aligned as in the conventional manner. Alignment marks and the like on the substrate 22 and the semiconductor element 21 are said to be the same as conventional manner.

Then, the aligned semiconductor element 21 and substrate 22 are put into a reflow oven to heat and melt the solder bumps 23. At the melting temperature (Tᵣ) of the solder bumps 23, the amount of thermal expansion of the substrate 22 is larger than that of the semiconductor element 21. Accordingly, as shown in FIG. 8B, the amount of deformation of the solder bump 23A is reduced according to the original amount of shift Δr. During the cooling process from this state to the solidification temperature (Tₘ) and further to room temperature (Tᵣₜ), the solder bump 23A distorts towards the chip edge side according to the original amount of shift Δr as shown in FIG. 8C. In other words, the stress intensity factor in the notch shape of the solder bump 23A in the corner portion on the chip edge side is less than or equal to that in the corner portion on the chip center side.

The semiconductor element 21 and the substrate 22 are connected in flip chip connection in this manner. Thereafter, the object semiconductor device 20 is manufactured through processes of cleaning of the flux agent and injection and curing of the underfill resin 24 between the semiconductor element 21 and the substrate 22. It should be noted that though an example to perform sealing with an underfill resin by a capillary flow method is explained, it is also possible to use a sealing method using a no-flow underfill resin without using a flux agent, for instance.

A process for manufacturing the semiconductor device of the above-described embodiment uses an ordinary reflow oven for melting of the solder bumps 23, and the semiconductor element 21 and the substrate 22 are heated to the melting temperature (Tᵣ) of the solder bumps 23. Here, since the solder bumps 23 are formed on the semiconductor element 21, it is necessary to heat the semiconductor element 21 to the melting temperature (Tᵣ) of the solder bumps 23. On the other hand, within a temperature range of performing connection without problem, the temperature of the substrate 22 (Tᵣ′) can be lower than the melting temperature (Tᵣ).

When the solder bump 23 is melted, it is possible to use a temperature (Tᵣ′) lower than the melting temperature (Tᵣ) as a temperature of the substrate 22. That is, by applying a heating condition in which the substrate temperature (Tₛ) is lower than the semiconductor element temperature (T_{c}), the amount of thermal expansion in the substrate 22 is reduced. Thereby, it is possible to reduce the amount of deformation of the solder bumps 23. This leads to reduction of stress which causes cracking or the like, and thus it becomes possible to effectively restrain cracking or delamination of the low-k film 27 in the connection process (heating and cooling processes of the solder bumps 23). Therefore, a rate of failure occurrence of the semiconductor element 21 is further reduced, and reliability of the semiconductor device 20 is further improved.

For instance, the amount of shift Δr of the first electrode pad 25 and the second electrode pad 29 at the melting temperature Tᵣ(>Tₛ) of the solder bumps 23 is expressed the following equation (7).
Δr={(Tₛ−Tᵣₜ)·Eₛ−(Tᵣ−Tᵣₜ)·E_{c}}·r (7)

When the substrate temperature Tₛ is lower than the solidification temperature Tₘ of the solder bumps 23 (Tₛ<Tₘ), the amount of shift Δr at the solidification temperature Tₘ becomes small as expressed by the following equation (8), and the amount of deformation of the solder bumps 23 is reduced.
Δr={(Tₛ−Tᵣₜ)·E_{c}}·r (8)

However, when the final shape of the solder bumps 23 is distorted towards the chip center as shown in FIG. 10C, cracking is apt to occur. Accordingly, in the shape of the solder bumps 23 cooled to room temperature, the stress intensity factor K_{ce} in the corner portion on the chip edge side is made smaller than or equal to the stress intensity factor K_{cc} in the corner portion on the chip center side as shown in FIG. 6. In such a case, since the reduction of the amount of deformation of the solder bumps 23 leads to reduction of the amount of shift Δr which is established in advance, it becomes possible to further enhance the reliability of the connecting portion owing to the solder bumps 23. In other words, it restrains occurrence of cracking or the like in the semiconductor element 21 with the low-k film 27, and at the same time, it can enhance the reliability of the connecting portion at room temperature.

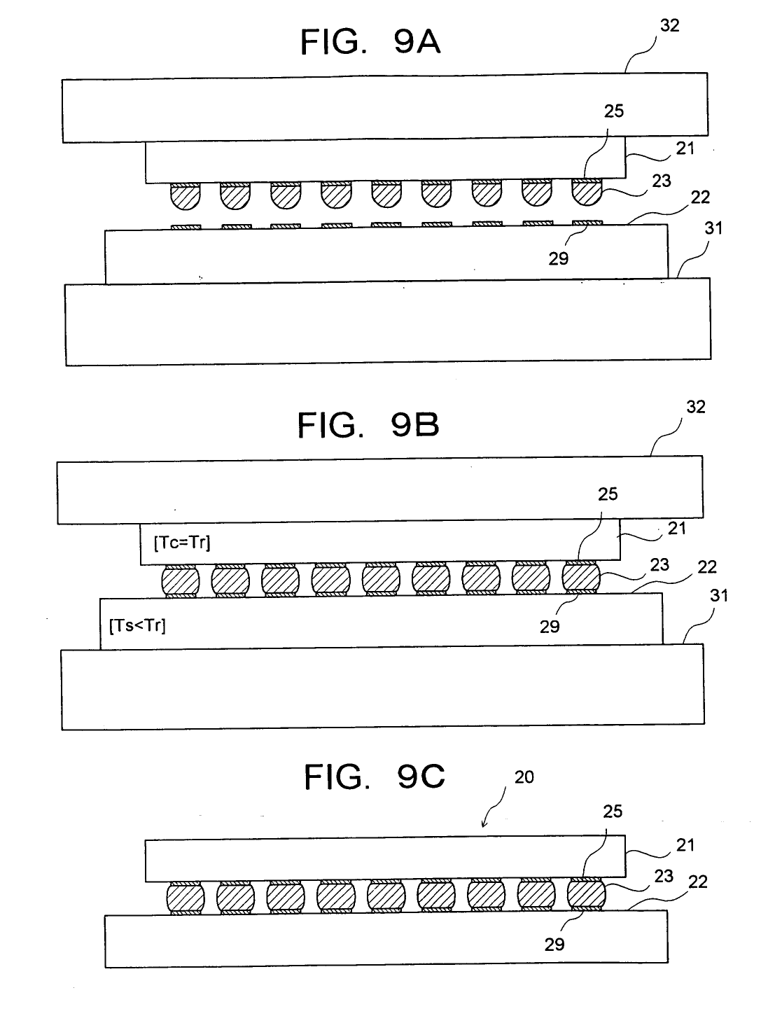

FIGS. 9A, 9B, and 9C are views showing an embodiment of the manufacturing process of the semiconductor device to which a heating condition to make the substrate temperature (Tₛ) lower than the semiconductor element temperature (T_{c}) is applied. The manufacturing process of the semiconductor device according to this embodiment will be explained. As shown in FIG. 9A, the substrate 22 is arranged on a bonding stage 31, and a flux agent (not shown) is applied on the surface thereof. Then, the semiconductor element 21 is aligned to the substrate 22 using a bonding tool 32. The bonding tool 32 is provided with a mechanism to locally heat the solder bumps 23 from the semiconductor element 21 side. As the heating mechanism, a pulse heat bonding can be used for instance.

Using a heating mechanism embedded in the bonding tool 32, the solder bumps 23 are locally heated to melt from the semiconductor element 21 side as shown in FIG. 9B. At this time, the temperature (T_{c}) of the semiconductor element 21 reaches the melting temperature Tᵣ of the solder bumps 23, but the temperature (Tₛ) of the substrate 22 is set to be lower than the melting temperature Tᵣ (Tₛ<Tᵣ) within a range of not causing trouble with connection. Under such a heating condition, the solder bumps 23 are melted, and the solder bumps 23 are further cooled and solidified from such a temperature. As shown in FIG. 9C, the semiconductor device 20 in which the semiconductor element 21 and the substrate 22 are connected via the solder bumps 23 is obtained. Note that cleaning of a flux agent, injection and curing of an underfill resin, and the like are the same as the above-described embodiment.

It should be noted that the present invention is not limited to the above-described respective embodiments, but that it can be applied to various semiconductor devices in which a semiconductor element and a substrate are ed via solder bumps. The semiconductor element and the substrate forming the semiconductor device are not specifically limited, and various semiconductor elements and substrates can be used. Such semiconductor devices are included in the present invention. Embodiments of the present invention can be enlarged or modified within a technical idea of the present invention, and the enlarged or modified embodiments are also included in the technical range of the present invention.

1. A semiconductor device, comprising:
a semiconductor element including a element body having an insulating film with a low dielectric constant, a group of electrode pads having first electrode pads provided on said element body, and a group of solder bumps having solder bumps respectively formed on said first electrode pads; and
a substrate provided with a group of electrode pads having second electrode pads ed to said first electrode pads via said solder bumps,
wherein said group of solder bumps is provided with a solder bump having a stress relaxation shape in which a stress intensity factor in a notch shape formed by said first electrode pad and the outline of said solder bump, when looking at a cross section through the center of said first electrode pad and said solder bump, is such that on the edge side of the semiconductor element it is less than or equal to its value on the center side thereof.

2. A semiconductor device according to claim 1, wherein said solder bump has the shape in which said stress intensity factor is smaller on the edge side than or equal to the center side of said semiconductor element.

3. A semiconductor device according to claim 1, wherein said solder bump has the shape to relax stress added to said insulating film with a low dielectric constant during a process of cooling said solder bumps from melting temperature to room temperature.

4. A semiconductor device according to claim 1, wherein said group of solder bumps is arranged in a matrix, and the solder bump having said stress relaxation shape is arranged at least in corner portion of said group of solder bumps.

5. A semiconductor device according to claim 1, wherein said group of solder bumps is arranged in a matrix, and the solder bump having said stress relaxation shape is arranged in corner portion of said group of solder bumps.

6. A semiconductor device according to claim 1, wherein the solder bump having said stress relaxation shape is formed on said first electrode pad with center shifted to the edge side of said semiconductor element from the center of said second electrode pad at room temperature.

7. A semiconductor device according to claim 6, wherein the amount of shift (Δr) between the centers of said first electrode pad and said second electrode pad is in a range of 10 μm≦Δr≦(Tᵣ−Tᵣₜ)·r·(Eₛ−E_{c}), where a thermal expansion coefficient of said semiconductor element is E_{c}, a thermal expansion coefficient of said substrate is Eₛ, melting temperature of said solder bump is Tᵣ, and room temperature is Tᵣₜ.

8. A semiconductor device according to claim 1, wherein said semiconductor element has a circuit portion formed with said insulating film with a low dielectric constant and Cu wirings, and said first electrode pads are electrically connected to said Cu wirings.

9. A semiconductor device according to claim 1, wherein said insulating film with a low dielectric constant has a relative dielectric constant of 3.5 or lower.

10. A method of manufacturing a semiconductor device, comprising:
aligning a semiconductor element provided with a element body having an insulating film with a low dielectric constant and a first electrode pad arranged on said element body and a substrate having a second electrode pad so that said first electrode pad corresponds with said second electrode pad via a solder bump formed on said first electrode pad;
melting said solder bump by heating said aligned semiconductor element and substrate under a heating condition that the temperature of said substrate is lower than the temperature of said semiconductor element; and
cooling said melted solder bump and connecting the first electrode pad of said semiconductor element and the second electrode pad of said substrate via said solder bump having a shape in which a stress intensity factor in a notch shape formed by said first electrode pad and the outline of said solder bump, when looking at a cross section through the center of said first electrode pad and said solder bump, is such that on the edge side of the semiconductor element it is less than or equal to its value on the center side thereof.

11. A method of manufacturing the semiconductor device according to claim 10, wherein said solder bump is melted by heating said semiconductor element locally.

12. A method of manufacturing the semiconductor device according to claim 10, wherein said solder bump is formed on said first electrode pad having the center shifting to the edge side of said semiconductor element from the center of said second electrode pad at room temperature.

13. A method of manufacturing the semiconductor device according to claim 12, wherein the amount of shift (Δr) between the centers of said first electrode pad and said second electrode pad is in a range of 10 μm≦Δr≦(Tᵣ−Tᵣₜ)·r·(Eₛ−E_{c}), where a thermal expansion coefficient of said semiconductor element is E_{c}, a thermal expansion coefficient of said substrate is Eₛ, melting temperature of said solder bump is Tᵣ, and room temperature is Tᵣₜ.

14. A method of manufacturing the semiconductor device according to claim 10, wherein said solder bump has a shape to relax stress added to said insulating film with a low dielectric constant during a process of cooling said solder bump from melting temperature to room temperature.

15. A method of manufacturing the semiconductor device according to claim 10, wherein said semiconductor element has a group of solder bumps arranged in a matrix, and said solder bump is disposed at least in the corner of said group of solder bumps.
